(19) United States
(12) Patent Application Publication
(10) Pub. No.: US 2024/0234234 A9
(43) Pub. Date: Jul. 11, 2024

(54) COPPER FILL FOR HEAT MANAGEMENT IN INTEGRATED CIRCUIT DEVICE

(71) Applicant: Intel Corporation, Santa Clara, CA (US)

(72) Inventors: Min Suet Lim, Gelugor (MY); Telesphor Kamgaing, Chandler, AZ (US); Ilan Ronen, Hadera (IL); Kavitha Nagarajan, Bangalore KA (IN); Chee Kheong Yoon, Beyan Lepas (MY); Chu Aun Lim, Hillsboro, OR (US); Eng Huat Goh, Penang (MY); Jooi Wah Wong, Bukit Mertajam (MY)

(73) Assignee: Intel Corporation, Santa Clara, CA (US)

(21) Appl. No.: 17/972,923

(22) Filed: Oct. 25, 2022

(51) Int. Cl. H01L 23/367; H01L 23/42; H01L 23/532

(52) U.S. Cl. CPC H01L 23/367; H01L 23/42; H01L 23/53233

(57) ABSTRACT

Described herein are integrated circuit devices that include semiconductor devices near the center of the device, rather than towards the top or bottom of the device. In this arrangement, heat can become trapped inside the device. Metal fill, such as copper, is formed within a portion of the device, e.g., over the semiconductor devices and any front side interconnect structures, to transfer heat away from the semiconductor devices and towards a heat spreader.

### BACKGROUND

Integrated circuit (IC) devices generate heat during operation that can degrade the performance of the devices. Reducing heat in an IC device can improve performance. If a device layer (e.g., transistors) are near the top or bottom of the IC package, heat can travel out of the top or bottom of the IC, e.g., to an integrated heat spreader and out of the IC package.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example IC architecture in which heat may become trapped, according to some embodiments of the present disclosure.

FIG. 2 illustrates an example IC device with metal fill over the device layer(s), according to some embodiments of the present disclosure.

FIG. 3 illustrates a cross-section of an IC device having a device layer, interconnect layers, and metal fill, according to some embodiments of the present disclosure.

FIGS. 4A through 4M illustrate a process for forming an IC device with metal fill, according to some embodiments of the present disclosure.

FIG. 5 is a cross-section of an IC device having a thermal interface material surrounding a metal fill, according to some embodiments of the present disclosure.

FIG. 6 is a cross-section of an IC package coupled to a cooling device, according to some embodiments of the present disclosure.

FIGS. 7A and 7B are top views of, respectively, a wafer and dies that may include metal fill in accordance with any of the embodiments disclosed herein.

FIG. 8 is a cross-sectional side view of an IC package that may include metal fill in accordance with any of the embodiments disclosed herein.

FIG. 9 is a cross-sectional side view of an IC device assembly that may include metal fill in accordance with any of the embodiments disclosed herein.

FIG. 10 is a block diagram of an example computing device that may include metal fill in accordance with any of the embodiments disclosed herein.

FIG. 11 is a block diagram of an example processing device that may include metal fill in accordance with any of the embodiments disclosed herein.

### DETAILED DESCRIPTION

Overview

Heat regulation is an important challenge in semiconductor devices. In general, when transistors operate at lower temperatures, they have improved performance. For example, electron mobility in transistors improves at lower temperatures, which can lead to increased drive currents. In addition, transistors at lower temperatures generally experience lower leakage than transistors operating at higher temperatures. These factors can result in smoother operations when an IC device (e.g., a computing device or transistor-based memory device) is operating at a lower temperature. For example, the voltage levels required to turn on a semiconductor device may be lower when the semiconductor device is at a lower temperature, due to the increased drive current. Thus, a semiconductor device at a lower temperature may have lower power consumption than if the device is at a higher temperature. Another effect of lower temperature in an IC device is that it increases the conductivity of the conductive components, which can also increase the speed of operations.

In previous IC arrangements, semiconductor devices (e.g., transistors) are formed over a substrate, and interconnect structures are formed over the semiconductor devices. Power and signal delivery may extend from the opposite side of the IC and through the interconnect structures. Heat primarily exits the device through the substrate side. For example, a heat spreader may be formed over the substrate to help heat from the transistors leave the IC, keeping the semiconductor materials cool.

Another IC architecture positions semiconductor devices nearer to the middle of the package. Interconnect structures may be formed both above and below the semiconductor devices. This architecture can improve power and signal delivery, e.g., by allowing power delivery from one side (e.g., the back side of the semiconductor devices), and signal delivery from the other side (e.g., the front side of the semiconductor devices). As another example, power delivery and signal input/output (I/O) may be on one side of the device layers (e.g., on a back side), while transfer of signals between components (e.g., between different processing units) in the package may be routed through interconnects on the opposite side of the device layers (e.g., on a front side).

When the transistors are in the middle of the IC, however, heat can get trapped within the IC package, rather than quickly dissipating out the front or back side, as in the previous architecture. Heating up the semiconductor devices may reduce performance, as discussed above. The heat trapping effect may be further exacerbated by inclusion of dummy layers on one or both sides of the semiconductor devices. In the manufacture of an IC, the number of interconnect layers, also referred to as metal layers, may be fixed. If a particular IC design does not use all of the layers, a dummy region is fabricated. The dummy region includes an insulating material, and may include metal portions that are not connected to other layers.

Embodiments of the present disclosure may improve on at least some of the challenges and issues described above by providing a metal fill region over the semiconductor devices. The metal fill may replace dummy interconnect layers and provide better heat transfer than the dummy layers, to move heat away from the semiconductor devices and toward a heat spreader or heat sink. The metal fill region may be formed on a front side of the semiconductor devices. In some embodiments, different portions of an IC have different heights, e.g., a first region of the IC device may have one or more layers of interconnects formed over a front side of the semiconductor devices, while a second region may not have interconnects formed over the semiconductor devices. The metal fill may have different heights depending on the heights of the different regions of semiconductor devices and associated interconnect.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

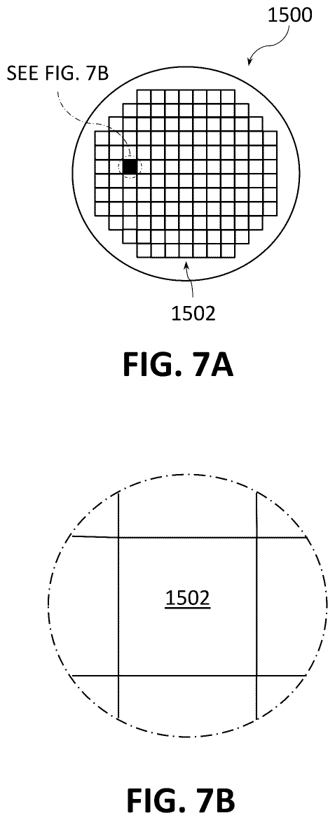

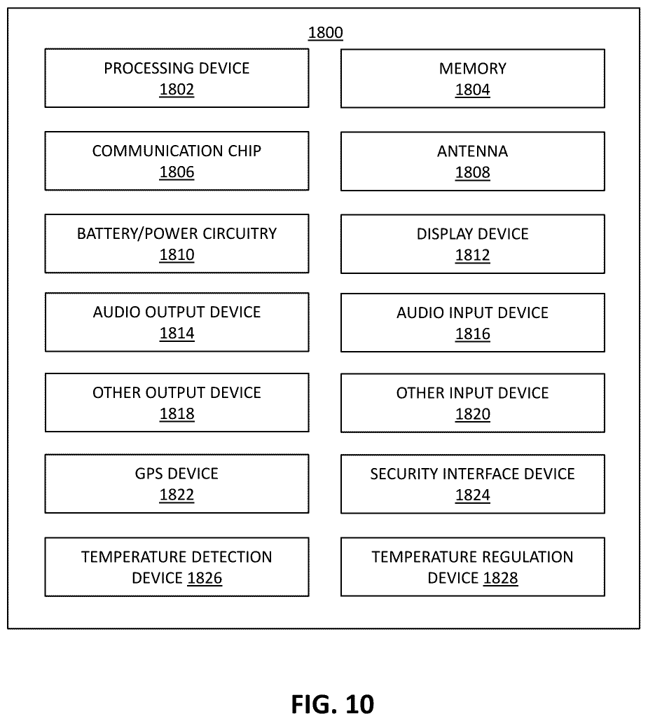

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 10.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with metal fill regions as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example IC with Dummy Region Over Device Layer

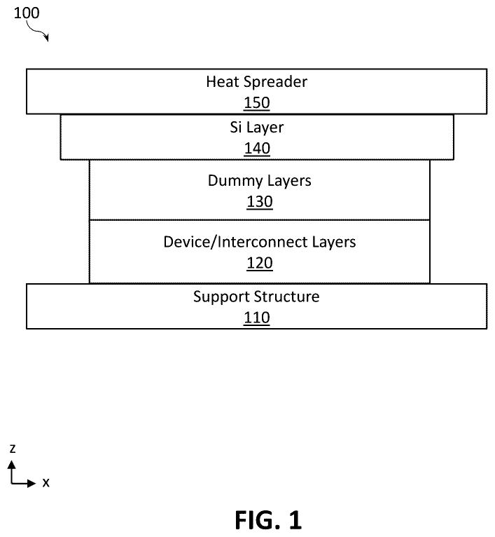

FIG. 1 illustrates an example IC architecture in which heat may become trapped. An IC device 100 includes a support structure 110, device and interconnect layers 120 over the support structure 110, and dummy layers 130 over the device and interconnect layers 120. The IC device 100 further includes a silicon layer 140 and a heat spreader 150 over the dummy layers 130.

The device and interconnect layers 120 include a set of interconnect layers over the support structure 110. These interconnect layers may enable power and signal delivery to the IC device 100. The interconnect layers may also enable intradevice communication. One or more device layers including semiconductor devices (e.g., transistors) are over the interconnect layers. In some cases, additional interconnect layers may be over the device layer(s). Dummy layers 130 are over the device and interconnect layers 120. The dummy layers 130 may be directly over a device layer, or a portion of a device layer. Alternatively, a dummy layer 130, or a portion of a dummy layer 130, may be over an interconnect layer.

In this arrangement, the device (transistor) layer(s) are neither at the top nor the bottom of the IC device 100. The dummy layers 130 sit between the device layer(s) and the heat spreader 150, and the dummy layers 130 may trap the heat within the device/interconnect layers 120. First, the dummy layers 130 sitting between the device/interconnect layers 120 and the heat spreader 150 create physical distance between the semiconductor devices and the heat spreader 150. Furthermore, the materials forming the dummy layers 130, and in particular, a dielectric material in the dummy layers 130, are typically not good conductors of heat, and do not efficiently move heat from the device/interconnect layers 120 to the heat spreader 150. While metal materials that may form interconnects (e.g., copper) can move heat out of a device, the dummy layers 130 are not connected to the device/interconnect layers 120, and therefore may not effectively transfer heat out of the IC device 100.

Example IC with Metal Fill Over Device Layer

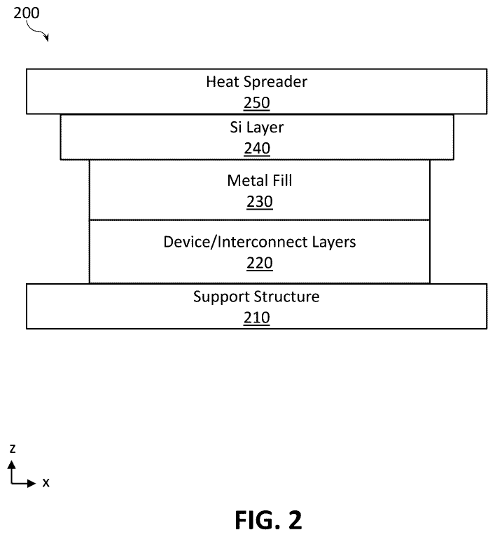

FIG. 2 illustrates an example IC device with metal fill over the device layer(s), according to some embodiments of the present disclosure. The IC device 200 includes a support structure 210, device and interconnect layers 220 over the support structure 210, and metal fill 230 over the device and interconnect layers 220. The metal fill 230 replaces some or all of the dummy layers 130 shown in FIG. 1. The IC device 200 further includes a silicon layer 240 and a heat spreader 250 over the metal fill 230. The metal fill 230 is a layer of conductive material, such as copper or another metal that is a good conductor of heat. The metal fill 230 takes heat from the device/interconnect layers 220 and transfers the heat upwards towards the heat spreader 250, which moves the heat out of the IC device 200. The metal fill 230 is not electrically coupled to the device and interconnect layers 220.

The support structure 210 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which an IC device as described herein may be built falls within the spirit and scope of the present disclosure. The silicon layer 240 may be similar to the support structure 210 described above. In some embodiments, a different material than silicon may be used between the metal fill 230 and the heat spreader 250, or one or more additional layers not illustrated in FIG. 2 may be included.

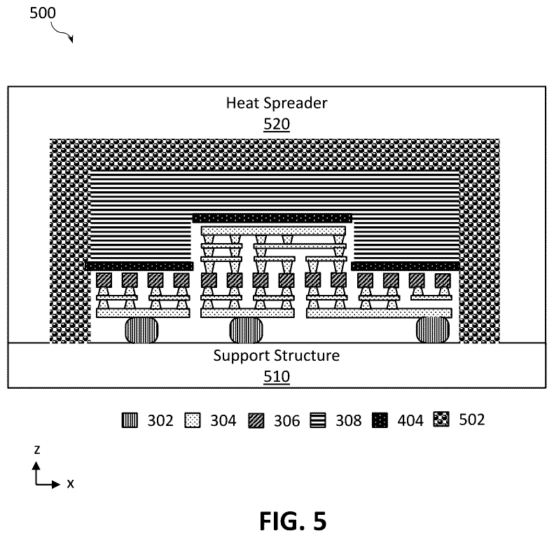

The heat spreader 250 may be formed from a metal material that is a good conductor of heat, such as copper. The heat spreader 250 may also act as a protective casing around the IC device 200. While the heat spreader 250 is illustrated as covering the top of the device 200, the heat spreader 250 may also cover the sides of the device 200, e.g., as illustrated in FIG. 5.

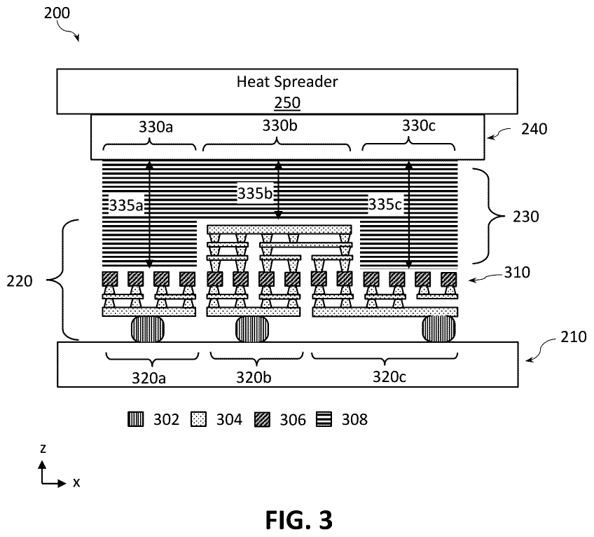

FIG. 3 illustrates a cross-section of an IC device having a device layer 310, interconnect layers over and under the device layer 310, and metal fill, according to some embodiments of the present disclosure. FIG. 3 illustrates the device/interconnect layers 220 and metal fill 230 in greater detail. The device/interconnect layers 220 include solder balls 302, interconnect structures 304, and transistors 306. The transistors 306 are arranged in a device layer 310. While a single device layer 310 is illustrated, the IC device 200 may include multiple device layers at different heights in the z-direction. The metal fill 230 is illustrated as including a copper fill 308. In this example, the device/interconnect layers 220 include three different regions 320a, 320b, and 320c, where different regions are located at different positions along the x-axis in the coordinate system shown. The different regions 320a, 320b, and 320c may correspond to different sub-devices with different functionalities. For example, the region 320a may be a central processing unit (CPU), the region 320c may be a graphical processing unit (GPU), and the region 320b may be a communications interface providing input and output for the IC device 200. In other embodiments, different regions may be associated with different functionalities. For example, other regions may include memory, digital signal processors (DSPs), various types of communications interfaces, other types of processors, etc.

Different regions of the device/interconnect layers 220 are illustrated as having different heights, where height refers to a dimension in the z-direction in the coordinate system shown. In particular, the region 330b, which corresponds to the region 320b and a portion of the region 320c, extends higher than the regions 330a and 330c. In this case, the device/interconnect layers 220 include interconnect layers formed over the transistors 306 in the region 330b. The interconnect layers in the region 330b may provide interconnections between the communications interface and the GPU in the example described above. In other embodiments, different regions may also have transistors 306 formed in various layers at various heights, rather than a single layer 310 extending across the different regions 320.

In this example, the copper fill 308 is arranged based on the heights of the regions below. For example, a portion of copper fill 308 in the region 330a extends lower in the z-direction than a portion of copper fill 308 in the region 330b, because the device/interconnect layers 220 in the region 330a has a shorter height than in the region 330b. This can help promote the heat transfer, because the copper fill 308 is positioned closely to the transistors 306. In some IC architectures, the transistors 306 in the lower-height regions of the device/interconnect layers 220 may operate more frequently than transistors 306 in the taller regions. For example, if the region 320a is a CPU and the region 320b is a communications interface, the transistors 306 in the CPU 320a are typically more active than the transistors 306 in the communications interface 320b. Extending the copper fill 308 downwards and close to the transistors of the CPU 320a can provide more efficient heat transfer than if the copper fill 308 did not extend down in the z-direction, e.g., if the base of the copper fill 308 were a plane over the top of the region 330b.

FIG. 3 illustrates the heights 335 of the copper fill 308 in the three regions 330. In this example, the heights 335a and 335c are the same, and the height 335b is smaller than the heights 335a and 335c. The heights 335 may also be referred to as thicknesses of the copper fill 308, with the copper fill 308 in the regions 330a and 330c having greater thickness than the copper fill 308 in the region 330b. The copper fill 308 may have a thickness in one or more of the regions that is between, e.g., 1 nanometer and 50 microns. In some embodiments, the thickness of the copper fill 308 may be greater than the thickness of a metallization layer. For example, the copper fill 308 may have a thickness of at least, e.g., 200 nanometers, 500 nanometers, at least 1 micron, at least 2 microns, at least 5 microns, at least 10 microns, etc. The height of the copper fill 308 can depend on the overall size of the IC device 200, and in particular, the height of the metallization layers in the fabrication process.

While FIG. 3 illustrates metal fill being formed over an IC device having three regions 330a, 330b, and 330c having two different heights, in other embodiments, the IC device may have more or fewer regions and more or fewer heights (e.g., a single height across the IC device, two regions of two different heights, three regions each at a different height, four regions at various different heights, etc.).

The computing regions 320a, 320b, and 320c are formed over interconnect layers that include a metallization stack and one or more solder balls 302. The solder balls 302 provide electrical and mechanical contact to the support structure 210, which may be in turn be coupled to other external components, e.g., for input and output of signals, and input of power to the IC device 200. The IC device 200 may have other alternative configurations to route electrical signals from the device/interconnect layers 220 and out of the IC device 200. For example, the solder balls 302 may be replaced by or may further include other analogous features (e.g., posts) that route the electrical signals to external components.

The interconnects 304 form layers of a metallization stack, where each layer may include an insulating material, a dielectric material formed in multiple layers, as known in the art. The insulating material is not specifically shown in FIG. 3. The interconnects 304 may include one or more conductive traces and conductive vias, providing one or more conductive pathways through the insulating materials. The interconnects 304 may be formed from appropriate conductive material, such as copper, silver, nickel, gold, aluminum, or other metals or alloys, for example. The conductive pathways may be connected to one another in any suitable manner. While all of the interconnects 304 in FIG. 3 are illustrated as being formed form the same material, in other embodiments, different materials may be used, e.g., the interconnects over a front side of the device layer 310 may include a different material from the interconnects below the back side of the device layer 310. Although FIG. 3 illustrate a specific number and arrangement of conductive pathways formed by the interconnects 304, these are simply illustrative, and any suitable number and arrangement may be used.

In some embodiments, the insulating material surrounding the interconnects 304 and/or the transistors 306 may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imagable dielectrics, and/or benzocyclobutene-based polymers). In some embodiments, the insulating material may include a semiconductor material, such as silicon, germanium, or a III-V material (e.g., gallium nitride), and one or more additional materials. For example, the insulating material may include silicon oxide or silicon nitride. An insulating material in the device layer 310 may be different from insulating materials around the interconnects 304 above and/or below the device layer 310.

The interconnects 304 form conductive pathways to route power, ground, and/or signals to/from various components of the device layer 310. The device layer 310 includes logic devices, e.g., transistors 306, coupled to the interconnect 304, e.g., through conductive contacts. The device layer 310 may include semiconductor material systems including, for example, N-type or P-type materials systems, as active materials (e.g., as channel materials of transistors). In some embodiments, the transistors 306 may include substantially monocrystalline semiconductors, such as silicon or germanium.

In some embodiments, the transistors 306 may include compound semiconductors, e.g., compound semiconductors with a first sub-lattice of at least one element from group III of the periodic table (e.g., Al, Ga, In), and a second sub-lattice of at least one element of group V of the periodic table (e.g., P, As, Sb). In some embodiments, the transistors 306 may include a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

In some embodiments, the transistors 306 may be/include an intrinsic IV or III-V semiconductor material or alloy, not intentionally doped with any electrically active impurity. In alternate embodiments, nominal impurity dopant levels may be present within the transistors 306, for example to set a threshold voltage Vt, or to provide halo pocket implants, etc. In such impurity-doped embodiments however, impurity dopant level within the active materials may be relatively low, for example below about 10¹⁵ cm⁻³, and advantageously below 10¹³ cm⁻³.

For exemplary P-type transistor embodiments, transistors 306 may advantageously be formed using group IV materials having a high hole mobility, such as, but not limited to, Ge or a Ge-rich SiGe alloy. For some exemplary embodiments, such active materials may have a Ge content between 0.6 and 0.9, and advantageously is at least 0.7.

For exemplary N-type transistor embodiments, the transistors 306 may advantageously be formed using a III-V material having a high electron mobility, such as, but not limited to InGaAs, InP, InSb, and InAs. For some such embodiments, the active material may be a ternary III-V alloy, such as InGaAs or GaAsSb. For some InₓGa₁₋ₓAs fin embodiments, In content in the such active material may be between 0.6 and 0.9, and advantageously at least 0.7 (e.g., In_{0.7}Ga_{0.3}As).

In some embodiments, the transistors 306 may be formed from thin-film materials, in which embodiments the transistors 306 could be thin-film transistors (TFTs). A TFT is a special kind of a field-effect transistor (FET), made by depositing a thin film of an active semiconductor material, as well as a dielectric layer and metallic contacts, over a support structure that may be a non-conducting (and non-semiconducting) support structure. During operation of a TFT, at least a portion of the active semiconductor material forms a channel of the TFT, and, therefore, the thin film of such active semiconductor material is referred to herein as a “TFT channel material.” This is different from conventional, non-TFT, transistors where the active semiconductor channel material is typically a part of a semiconductor substrate, e.g., a part of a silicon wafer. In various such embodiments, active materials of the transistors 306 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

In general, active materials of the transistors 306 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

Example Process for Forming IC with Metal Fill Over Device Layer

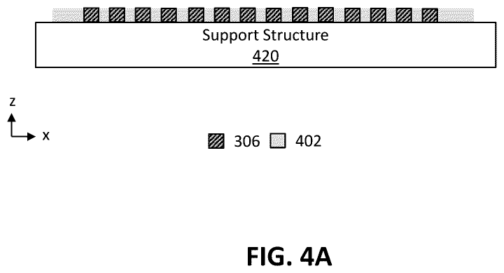

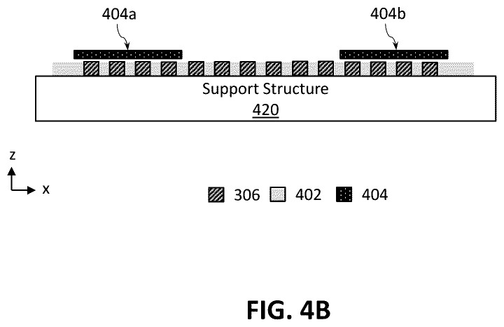

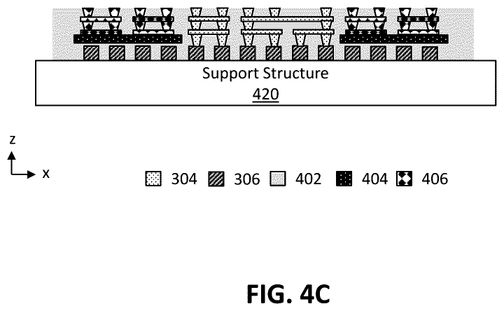

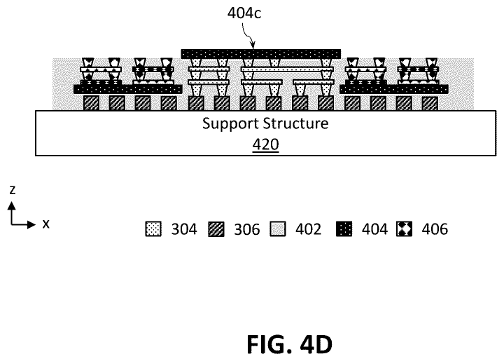

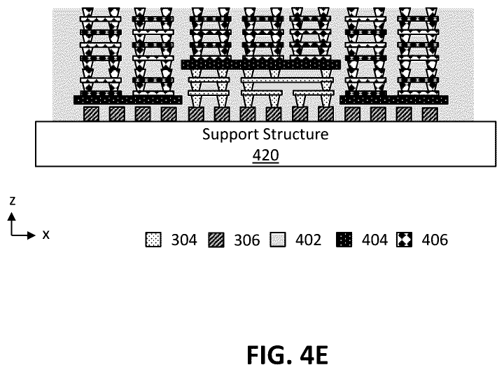

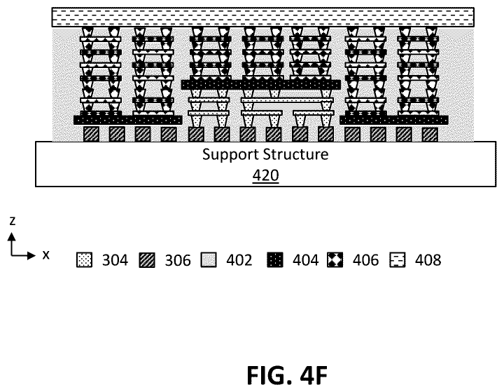

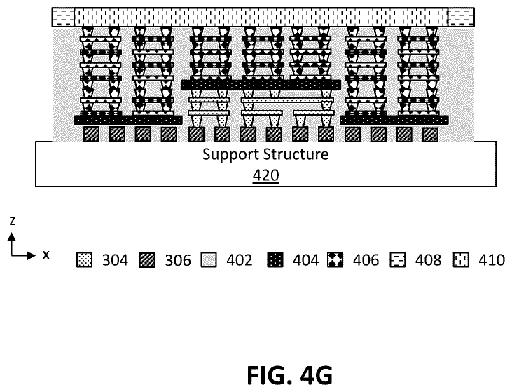

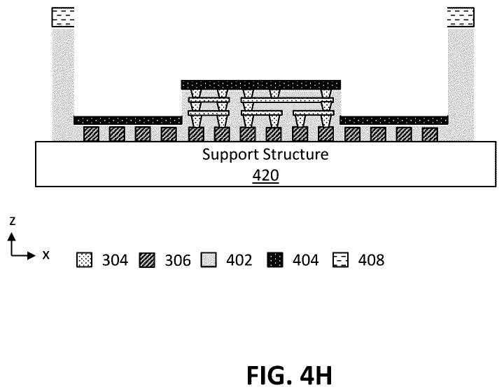

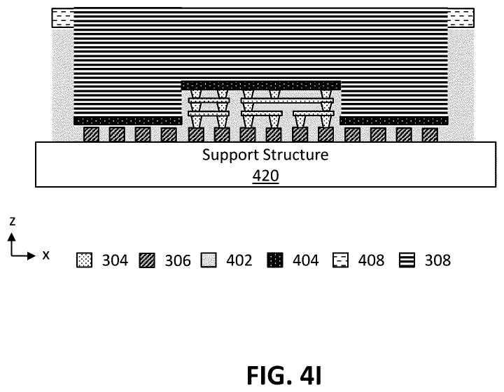

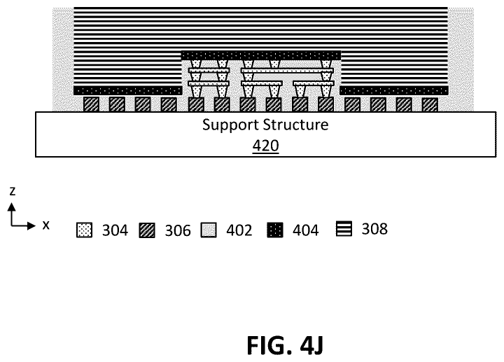

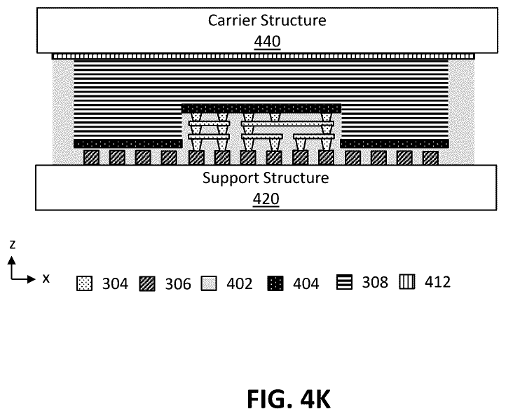

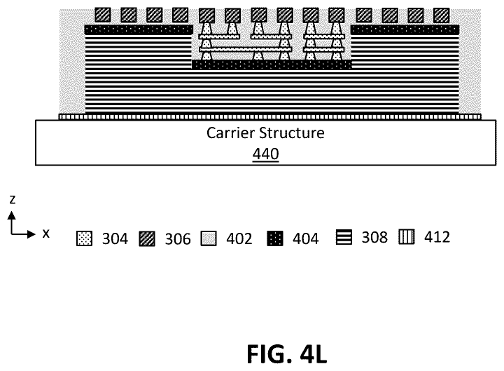

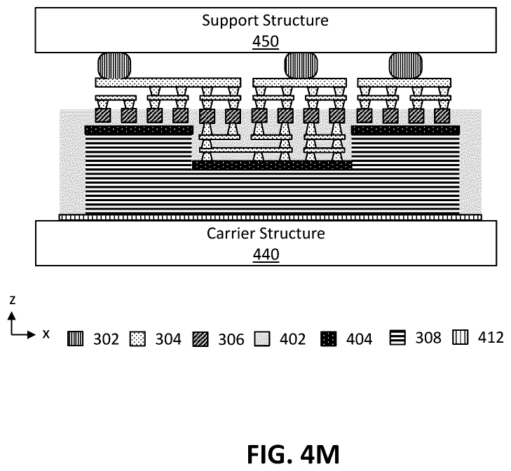

FIGS. 4A through 4M illustrate a process for forming an IC device with metal fill, according to some embodiments of the present disclosure. A number of elements referred to in the description of FIGS. 4A through 4M, 5, and 6 with reference numerals are illustrated in these figures with different patterns, with a legend showing the correspondence between the reference numerals and patterns being provided at the bottom of the drawing pages. Some of the same patterns were used in FIG. 3. For example, the legend in FIG. 4A illustrates that FIG. 4A uses different patterns to show transistors 306 and a dielectric material 402.

The transistors 306 may include any of the materials described above with respect to FIG. 3. The transistors 306 are surrounded by a dielectric material 402, which may include any of the dielectric materials described with respect to FIG. 3. FIG. 4A illustrates that the transistors 306 are formed over a support structure 420. The support structure 420 may be similar to the support structure 210 described with respect to FIG. 2. While not illustrated in FIG. 4A, in some embodiments, one or more metallization layers with interconnect structures are formed across a front side the transistors 306, i.e., the top side opposite the support structure 420.

In FIG. 4B, a layer of an etch stop 404 has been deposited over a portion of the transistors 306. As noted above, the etch stop 404 may be deposited over transistors 306 and any interconnect layers formed over the transistors 306, e.g., source, drain, and/or gate contacts, and interconnects for routing signals to the contacts on the front side of the transistors 306.

In this example, the etch stop 404 is arranged in two regions 404a and 404b, where the region 404a corresponds to the region 330a of FIG. 3, and the region 404b corresponds to the region 330c of FIG. 3. The etch stop 404 may be deposited using any suitable process for depositing a material over selected regions of the device. For example, any suitable lithographic process may be used in combination with a suitable etching process. In various embodiments, suitable lithographic processes may include photolithography, electron-beam lithography, etc., which may be used to define locations and dimensions for removing portions of a layer of etch stop, leaving behind the etch stop regions 404a and 404b. In various embodiments, suitable etching processes may include dry etch, wet etch, etc., which may be used to remove portions of the etch stop in regions defined by the lithographic process so that the regions 404a and 404b remain.

In FIG. 4C, interconnect 304 is formed over the etch stop 404 and the exposed transistors 306, i.e., the transistors not covered by the etch stop 404. This interconnect 304 corresponds to the interconnect in the region 330b in FIG. 3. In addition to the interconnect 304, dummy interconnect structures 406 are formed over the etch stop 404. The dummy interconnect 406 may include the same materials as the interconnect 304 but is not electrically coupled to other parts of the device (e.g., the dummy interconnect 406 is not coupled to the interconnect 304 or the transistors 306). In other embodiments, the dummy interconnect 406 may be formed from a different material from the interconnect 304.

The interconnect 304 and dummy interconnect 406 are surrounded by the dielectric material 402. As noted above, in some embodiments, the dielectric material 402 around the transistors 306 may be different from the dielectric material around the interconnect 304 and dummy interconnect 406. The interconnect 304 and dummy interconnect 406 may be formed using processes for patterning and depositing interconnect as are known in the art.

At FIG. 4D, another layer of an etch stop 404 is deposited over the interconnect 304. This etch stop region, labelled 404c, may be deposited in a similar manner as the etch stop regions 404a and 404b, e.g., using a lithographic process to cause the etch stop 404 to cover the interconnect 304 but not the dummy interconnect 406. While the etch stop region 404c is illustrated with the same pattern as the etch stop regions 404a and 404b, in other embodiments, different materials may be used.

At FIG. 4E, additional layers of dummy interconnect 406 are fabricated in additional layers over the etch stop region 404c and previously-fabricated dummy interconnect structures 406. As noted above, in some cases, a fabrication process may include a fixed number of metallization layers, even if the metallization layers are not used. In this example, a number of dummy interconnect layers are formed across the full device.

In FIG. 4F, a photoresist 408 is deposited over the dummy interconnect 406. For example, the photoresist 408 may be spin coated over the dummy interconnect 406.

In FIG. 4G, the photoresist 408 is patterned, which changes a physical property of a portion 410 of the photoresist 408. For example, a patterned mask may be arranged over the photoresist 408, and the portion 410 of the photoresist 408 is exposed to patterned actinic radiation through the patterned mask. The patterned photoresist 410 can then be removed through a developing process to form an opening in the photoresist layer.

In FIG. 4H, the patterned photoresist 410 has been removed, forming an opening in the photoresist 408, and the dummy interconnect 406 and dielectric material 402 around the dummy interconnect 406 have been removed. Said another way, the region between under the patterned photoresist 410 and down to the etch stop 404 has been removed, e.g., through one or more etching processes.

In FIG. 4I, a metal fill is deposited in the region that had the dummy interconnect 406. For example, a seeding and electroplating process may be used to deposit the metal fill. In this example, the metal fill is a copper fill 308, but in other embodiments, different thermally conductive materials (e.g., other types of metal) may be used. The copper fill 308 extends to the tops of the etch stop regions 404a, 404b, and 404c, which, as noted above, can have different heights. In this example, the dielectric 402 remains along the sides of the copper fill 308.

At FIG. 4J, the front side of the device is polished to remove the photoresist 408 and, in this case, a portion of the copper fill 308 and a portion of the dielectric 402 below the photoresist layer. For example, a chemical mechanical planarization, or chemical mechanical polishing, process may be used to planarized the front face of the device. In other embodiments, the copper fill 308 is not thinned.

At FIG. 4K, a carrier structure 440 is bonded to the front face of the device, e.g., to the copper fill 308. In some embodiments, an oxide layer 412 or other form of bonding layer is deposited over the copper fill 308 prior to attaching the carrier structure 440. The carrier structure 440 may be similar to any of the support structures described above.

At FIG. 4L, the device is flipped, and the support structure 420 is removed, e.g., by grinding. In some embodiments, a portion of the support structure 420 remains. Through-substrate vias (TSVs) may be formed through the remaining portion of the support structure 420.

At FIG. 4M, back end interconnects 304 and solder balls 302 are fabricated over the exposed side of the transistors 306, and a support structure 450 is coupled to the solder balls 302. The support structure 450 may be the support structure 210 shown in FIGS. 2 and 3. The device illustrated in FIG. 4M is similar to the device shown in FIG. 2 but flipped upside-down. The carrier structure 440 may be replaced with a heat spreader 250 to provide additional heat transfer from the copper fill 308 and out of the device.

Example Device with Thermal Interface Material

FIG. 5 is a cross-section of an IC device 500 having a thermal interface material surrounding a metal fill, according to some embodiments of the present disclosure. In this example, a thermal interface material (TIM) 502 surrounds the copper fill 308 on three sides. The TIM 502 further extends to the front side of the support structure 510. The TIM may be any material that can be inserted between the device/interconnect layers 220 and the copper fill 308, on one side of the TIM 502, and the heat spreader 520, on the other side of the TIM 502, in order to enhance the thermal coupling between them. The TIM 502 may be a liquid TIM, a thermal paste, a thermal adhesive, thermal tape, or another type of TIM.

Example IC Device Coupled to Cooling Device

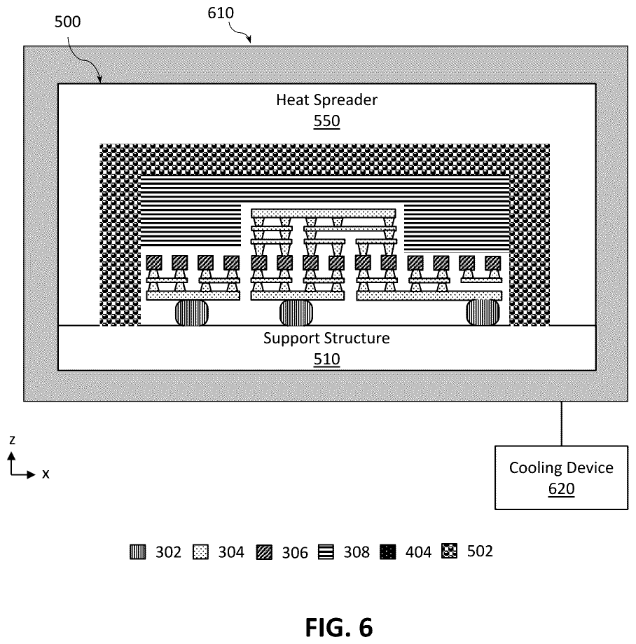

FIG. 6 is a cross-section of an IC package coupled to a cooling device, according to some embodiments of the present disclosure. The device 500 illustrated in FIG. 5 is surrounded by a cooling structure 610. The cooling structure 610 is in thermal contact with the device 500 that the cooling structure 610 surrounds. The cooling structure 610 may include one or more coolant materials which are cooled by the cooling device 620. The coolant material may be, for example, a liquid or gas refrigerant material, or a material that undergoes phase transition between liquid and gas. For example, germanium telluride is a phase transition material that may be used as a coolant material. The tellurium content may be adjusted to tune the coolant material for different temperatures. In other embodiments, a solid coolant material, such as a metal layer, may be used to form the cooling structure 610. Additional particular coolant materials that may be used include bismuth telluride, silicon, germanium, and copper.

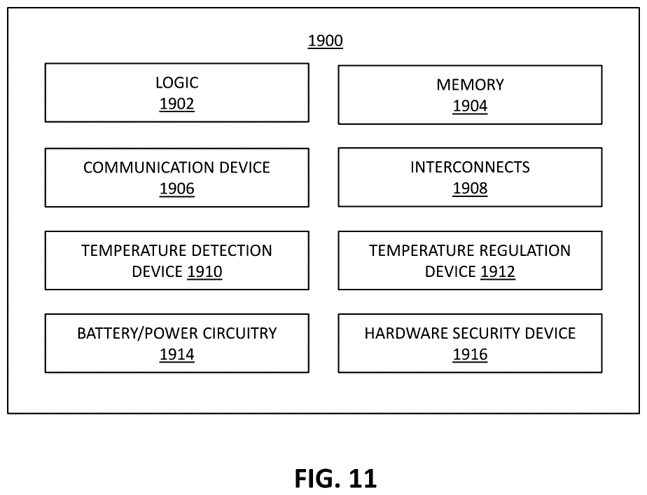

As noted above, the cooling structure 610 is coupled to a cooling device 620. The cooling device 620 cools the coolant material of the cooling structure 610. In some embodiments, the cooling device 620 is included in a same package as the IC device 500, i.e., the cooling device 620 and device 500 are included in the same package. In other embodiments, the cooling device 620 is on a separate package from the device 500, and coupled to the cooling structure 610. The cooling device 620 may be an embodiment of the temperature regulation device 1828 or 1912 described with respect to FIGS. 10 and 11. For example, the cooling device 620 may include a compressor (e.g., a screw compressor), an HVAC (heating, air conditioning, and cooling) device, a thermoelectric device, a heat exchanger, a direct refrigerant (e.g., liquid helium or liquid nitrogen), a cryogenic device (e.g., a cold finger), a turbo refrigeration device, or another type of cooling device.

In the example shown in FIG. 6, the cooling structure 640 surrounds the IC device 500 on the four illustrated sides. The cooling structure 610 may further surround the IC device 500 on all six sides of the IC device 500, thus completely surrounding the IC device 500. In some embodiments, the cooling structure 610 may not completely surround the IC device 500. For example, the cooling structure 610 may surround some portion of the sides of the IC device 500 (e.g., the cooling structure 610 may not be formed under the support structure 510), or the cooling structure 610 may not completely cover one or more sides of the IC device 500 (e.g., if there is a gap on a side of the IC device 500 not covered by the cooling structure 610).

Example Devices

Arrangements with one or more metal fill regions as disclosed herein may be included in any suitable electronic device. FIGS. 7-11 illustrate various examples of devices and components that may include metal fill as disclosed herein.

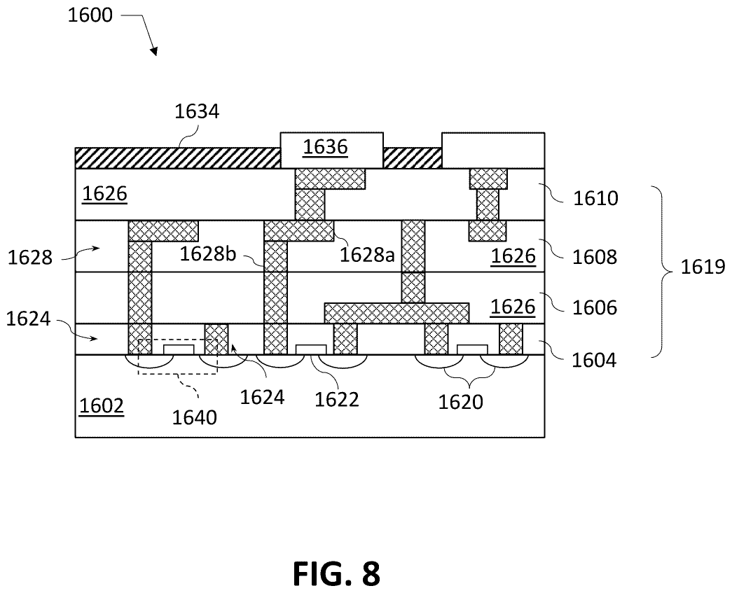

FIGS. 7A and 7B are top views of a wafer and dies that include one or more IC structures that may include metal fill formed over the semiconductor devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-6, or any further embodiments of the IC structures described herein). After the fabrication of the semiconductor product is complete (e.g., after manufacture of one or more IC devices with metal fill as described herein, included in a particular electronic component, e.g., in a computing device), the wafer 1500 may undergo a singulation process in which each of the dies 1502 is separated from one another to provide discrete “chips” of the semiconductor product. In particular, devices that include metal fill as disclosed herein may take the form of the wafer 1500 (e.g., not singulated) or the form of the die 1502 (e.g., singulated). The die 1502 may include one or more transistors (e.g., one or more of the transistors 1640 of FIG. 8, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 8 is a cross-sectional side view of an IC device 1600 that may include metal fill in accordance with any of the embodiments disclosed herein. The IC device 1600 may be formed on a substrate 1602 (e.g., the wafer 1500 of FIG. 7A) and may be included in a die (e.g., the die 1502 of FIG. 7B). The substrate 1602 may be any substrate as described herein. The substrate 1602 may be part of a singulated die (e.g., the dies 1502 of FIG. 7B) or a wafer (e.g., the wafer 1500 of FIG. 7A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include metal fill at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 8. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 8. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

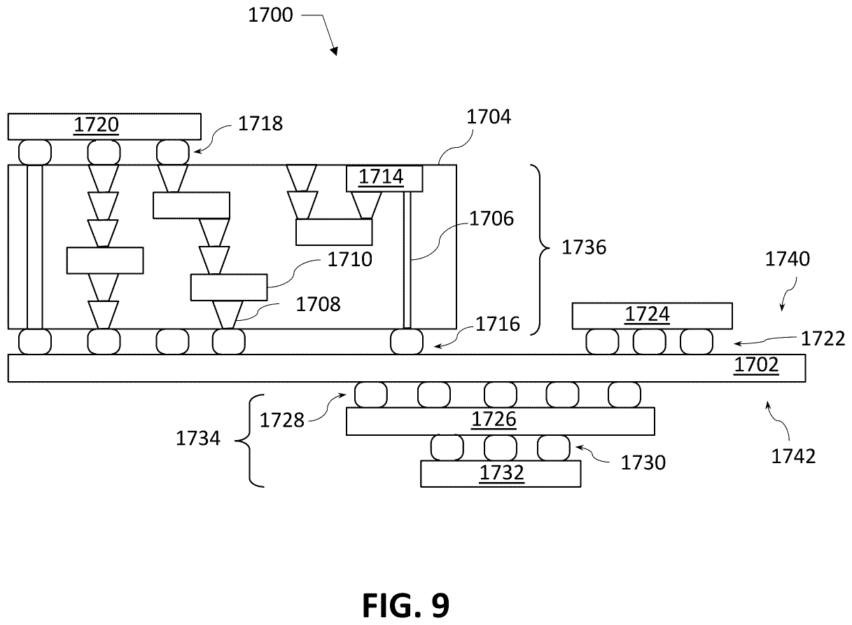

FIG. 9 is a cross-sectional side view of an IC device assembly 1700 that may include metal fill in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7B), an IC device (e.g., the IC device 1600 of FIG. 8), or any other suitable component. In some embodiments, the IC package 1720 may include metal fill, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example computing device 1800 that may include one or more components including metal fill in accordance with any of the embodiments disclosed herein. For example, any suitable ones of the components of the computing device 1800 may include a die (e.g., the die 1502 (FIG. 7B)) having metal fill. Any one or more of the components of the computing device 1800 may include, or be included in, an IC device 1600 (FIG. 8). Any one or more of the components of the computing device 1800 may include, or be included in, an IC device assembly 1700 (FIG. 9).

A number of components are illustrated in FIG. 10 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 10, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

In some embodiments, the computing device 1800 may include a temperature detection device 1826 and a temperature regulation device 1828.

The temperature detection device 1826 may include any device capable of determining temperatures of the computing device 1800 or of any individual components therein (e.g., temperatures of the processing device 1802 or of the memory 1804). In various embodiments, the temperature detection device 1826 may be configured to determine temperatures of an object (e.g., the computing device 1800, components of the computing device 1800, devices coupled to the computing device, etc.), temperatures of an environment (e.g., a data center that includes, is controlled by, or otherwise associated with the computing device 1800), and so on. The temperature detection device 1826 may include one or more temperature sensors. Different temperature sensors of the temperature detection device 1826 may have different locations within and around the computing device 1800. A temperature sensor may generate data (e.g., digital data) representing detected temperatures and provide the data to another device, e.g., to the temperature regulation device 1828, the processing device 1802, the memory 1804, etc. In some embodiments, a temperature sensor of the temperature detection device 1826 may be turned on or off, e.g., by the processing device 1802 or an external system. The temperature sensor detects temperatures when it is on and does not detect temperatures when it is off. In other embodiments, a temperature sensor of the temperature detection device 1826 may detect temperatures continuously and automatically or detect temperatures at predefined times or at times triggered by an event associated with the computing device 1800 or any components therein.

The temperature regulation device 1828 may include any device configured to change (e.g., decrease) temperatures, e.g., based on one or more target temperatures and/or based on temperature measurements performed by the temperature detection device 1826. A target temperature may be a preferred temperature. A target temperature may depend on a setting in which the computing device 1800 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1800 can be different. In some embodiments, cooling provided by the temperature regulation device 1828 may be a multi-stage process with temperatures ranging from room temperature to 4K or lower.

In some embodiments, the temperature regulation device 1828 may include one or more cooling devices. Different cooling device may have different locations within and around the computing device 1800. A cooling device of the temperature regulation device 1828 may be associated with one or more temperature sensors of the temperature detection device 1826 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1800 is satisfied. In response to determining that one or more temperature-related condition associated with the temperature of the computing device 1800 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1828 may operate with various cooling mechanisms, such as evaporation cooling, radiation cooling, conduction cooling, convection cooling, other cooling mechanisms, or any combination thereof. A cooling device of the temperature regulation device 1828 may include a cooling agent, such as a water, oil, liquid nitrogen, liquid helium, etc. In some embodiments, the temperature regulation device 1828 may be, for example, a dilution refrigerator, a helium-3 refrigerator, or a liquid helium refrigerator. In some embodiments, the temperature regulation device 1828 or any portions thereof (e.g., one or more of the individual cooling devices) may be connected to the computing device 1800 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1800 (or components thereof) can be reduced, while the computing efficiency may be improved. For example, when the computing device 1800 (or components thereof) operates at lower temperatures, energy dissipation (e.g., heat dissipation) may be reduced. Further, energy consumed by semiconductor components (e.g., energy needed for switching transistors of any of the components of the computing device 1800) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

FIG. 11 is a block diagram of an example processing device 1900 that may metal fill in accordance with any of the embodiments disclosed herein. For example, any suitable ones of the components of the processing device 1900 may include a die (e.g., the die 1502 (FIG. 7B)) having metal fill. Any one or more of the components of the processing device 1900 may include, or be included in, an IC device 1600 (FIG. 8). Any one or more of the components of the processing device 1900 may include, or be included in, an IC device assembly 1700 (FIG. 9). Any one or more of the components of the processing device 1900 may include, or be included in, a computing device 1800 (FIG. 10); for example, the processing device 1900 may be the processing device 1802 of the computing device 1800.

A number of components are illustrated in FIG. 11 as included in the processing device 1900, but any one or more of these components may be omitted or duplicated, as suitable for the application. In some embodiments, some or all of the components included in the processing device 1900 may be attached to one or more motherboards. In some embodiments, some or all of these components are fabricated on a single SoC die or coupled to a single support structure, e.g., to a single carrier substrate.

Additionally, in various embodiments, the processing device 1900 may not include one or more of the components illustrated in FIG. 11, but the processing device 1900 may include interface circuitry for coupling to the one or more components. For example, the processing device 1900 may not include a memory 1904, but may include display device interface circuitry (e.g., a connector and driver circuitry) to which a memory 1904 may be coupled.

The processing device 1900 may include logic circuitry 1902 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 1902 may include one or more circuits responsible for read/write operations with respect to the data stored in the memory 1904. To that end, the logic circuitry 1902 may include one or more I/O ICs configured to control access to data stored in the memory 1904.

In some embodiments, the logic circuitry 1902 may include one or more high-performance compute dies, configured to perform various operations with respect to data stored in the memory 1904 (e.g., arithmetic and logic operations, pipelining of data from one or more memory dies of the memory 1904, and possibly also data from external devices/chips). In some embodiments, the logic circuitry 1902 may be configured to only control I/O access to data but not perform any operations on the data. In some embodiments, the logic circuitry 1902 may implement ICs configured to implement I/O control of data stored in the memory 1904, assemble data from the memory 1904 for transport (e.g., transport over a central bus) to devices/chips that are either internal or external to the processing device 1900, etc. In some embodiments, the logic circuitry 1902 may not be configured to perform any operations on the data besides I/O and assembling for transport to the memory 1904.

The processing device 1900 may include a memory 1904, which may include one or more ICs configure to implement memory circuitry (e.g., ICs implementing one or more of memory devices, memory arrays, control logic configured to control the memory devices and arrays, etc.). In some embodiments, the memory 1904 may be implemented substantially as described above with reference to the memory 1804 (FIG. 10). In some embodiments, the memory 1904 may be a designated device configured to provide storage functionality for the components of the processing device 1900 (i.e., local), while the memory 1804 may be configured to provide system-level storage functionality for the entire computing device 1800 (i.e., global). In some embodiments, the memory 1904 may include memory that shares a die with the logic circuitry 1902.

In some embodiments, the memory 1904 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 1904 may be a memory that is not divided into hierarchical layer or levels in terms of access of its data.

In some embodiments, the memory 1904 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 1904 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 1904 may be arranged.

The processing device 1900 may include a communication device 1906, which may be implemented substantially as described above with reference to the communication chip 1806 (FIG. 10). In some embodiments, the communication device 1906 may be a designated device configured to provide communication functionality for the components of the processing device 1900 (i.e., local), while the communication chip 1806 may be configured to provide system-level communication functionality for the entire computing device 1800 (i.e., global).

The processing device 1900 may include interconnects 1908, which may include any element or device that includes an electrically conductive material for providing electrical connectivity to one or more components of, or associated with, a processing device 1900 or/and between various such components. Examples of the interconnects 1908 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 1900 may include a temperature detection device 1910 which may be implemented substantially as described above with reference to the temperature detection device 1826 (FIG. 10) but configured to determine temperatures on a more local scale, i.e., of the processing device 1900 of components thereof. In some embodiments, the temperature detection device 1910 may be a designated device configured to provide temperature detection functionality for the components of the processing device 1900 (i.e., local), while the temperature detection device 1826 may be configured to provide system-level temperature detection functionality for the entire computing device 1800 (i.e., global).

The processing device 1900 may include a temperature regulation device 1912 which may be implemented substantially as described above with reference to the temperature regulation device 1828 (FIG. 10) but configured to regulate temperatures on a more local scale, i.e., of the processing device 1900 of components thereof. In some embodiments, the temperature regulation device 1912 may be a designated device configured to provide temperature regulation functionality for the components of the processing device 1900 (i.e., local), while the temperature regulation device 1828 may be configured to provide system-level temperature regulation functionality for the entire computing device 1800 (i.e., global).

The processing device 1900 may include a battery/power circuitry 1914 which may be implemented substantially as described above with reference to the battery/power circuitry 1810 (FIG. 10). In some embodiments, the battery/power circuitry 1914 may be a designated device configured to provide battery/power functionality for the components of the processing device 1900 (i.e., local), while the battery/power circuitry 1810 may be configured to provide system-level battery/power functionality for the entire computing device 1800 (i.e., global).

The processing device 1900 may include a hardware security device 1918 which may be implemented substantially as described above with reference to the security interface device 1824 (FIG. 10). In some embodiments, the hardware security device 1918 may be a physical computing device configured to safeguard and manage digital keys, perform encryption and decryption functions for digital signatures, authentication, and other cryptographic functions. In some embodiments, the hardware security device 1918 may include one or more secure cryptoprocessors chips.

### Select Examples

The following paragraphs provide various examples of the embodiments disclosed herein.

Example 1 provides an IC device including an interconnect region including a plurality of metal layers; a device region including a plurality of transistors, the device region over the interconnect region; a heat spreader over the device region; and metal fill between the device region and the heat spreader, the metal fill having a thickness of at least 1 micron.

Example 2 provides the IC device of example 1, where the device region includes a first portion and a second portion, a second interconnect region is over the first portion of the device region.

Example 3 provides the IC device of example 2, where the metal fill has a first thickness over the second interconnect region and a second thickness over the second portion of the device region, the second thickness greater than the first thickness.

Example 4 provides the IC device of example 3, further including an etch stop material between the second portion of the device region and the metal fill having the second thickness.

Example 5 provides the IC device of example 2, where the metal fill has a same thickness over the second interconnect region and the second portion of the device region.

Example 6 provides the IC device of any of the preceding examples, where the metal fill includes copper.

Example 7 provides the IC device of any of the preceding examples, where the device region includes a CPU having a first height.

Example 8 provides the IC device of example 7, where the device region further includes a GPU having a second height different from the first height.

Example 9 provides the IC device of any of the preceding examples, where the interconnect region includes a power via and a signal via.

Example 10 provides the IC device of any of the preceding examples, further including a liquid TIM between the metal fill and the heat spreader.

Example 11 provides the IC device of any of the preceding examples, where the heat spreader is on at least one side of the IC device.

Example 12 provides the IC device of any of the preceding examples, further including a cooling structure formed around the device, the cooling structure in thermal contact with the heat spreader.

Example 13 provides an IC device including a first plurality of interconnect layers; a first device region over a first portion of the first plurality of interconnect layers; a second device region over a second portion of the first plurality of interconnect layers; and a metal region over the first device region and the second device region, where a first portion of the metal region formed over the first device region has a first thickness, and a second portion of the metal region formed over the second device region has a second thickness different from the first thickness.

Example 14 provides the IC device of example 13, further including a second plurality of interconnect layers over the first device region, where the first portion of the metal region is over the second plurality of interconnect layers.

Example 15 provides the IC device of example 13 or 14, further including a heat spreader over the metal region.

Example 16 provides the IC device of any of examples 13 through 15, where the first device region forms a first processing unit, and the second device region forms a second processing unit.

Example 17 provides the IC device of any of examples 13 through 15, where the first device region forms a first processing unit, and the second device region is a signal input/output region.

Example 18 provides a method for forming an IC device including forming a device layer including a plurality of transistors; forming a plurality of dummy layers over a first side of the device layer; removing at least a portion of the plurality of dummy layers; depositing a metal fill; and forming a plurality of interconnect layers over a second side of the device layer, the second side opposite the first side.

Example 19 provides the method of example 18, further including depositing an etch stop over at least a portion of the device layer, where removing at least the portion of the plurality of dummy layers includes removing dummy material to the etch stop.

Example 20 provides the method of example 18, where the metal fill includes a first portion having a first thickness and a second portion having a second thickness different from the first thickness.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
an interconnect region comprising a plurality of metal layers;
a device region comprising a plurality of transistors, the device region over the interconnect region;
a heat spreader over the device region; and
metal fill between the device region and the heat spreader, the metal fill having a thickness of at least 1 micron.

2. The IC device of claim 1, wherein the device region comprises a first portion and a second portion, a second interconnect region is over the first portion of the device region.

3. The IC device of claim 2, wherein the metal fill has a first thickness over the second interconnect region and a second thickness over the second portion of the device region, the second thickness greater than the first thickness.

4. The IC device of claim 3, further comprising an etch stop material between the second portion of the device region and the metal fill having the second thickness.

5. The IC device of claim 2, wherein the metal fill has a same thickness over the second interconnect region and the second portion of the device region.

6. The IC device of claim 1, wherein the metal fill comprises copper.

7. The IC device of claim 1, wherein the device region comprises a central processing unit (CPU) having a first height.

8. The IC device of claim 7, wherein the device region further comprises a graphics processing unit (GPU) having a second height different from the first height.

9. The IC device of claim 1, wherein the interconnect region comprises a power via and a signal via.

10. The IC device of claim 1, further comprising a liquid thermal interface material (TIM) between the metal fill and the heat spreader.

11. The IC device of claim 1, wherein the heat spreader is on at least one side of the IC device.

12. The IC device of claim 1, further comprising a cooling structure formed around the device, the cooling structure in thermal contact with the heat spreader.

13. An integrated circuit (IC) device comprising:
a first plurality of interconnect layers;
a first device region over a first portion of the first plurality of interconnect layers;
a second device region over a second portion of the first plurality of interconnect layers; and
a metal region over the first device region and the second device region, wherein a first portion of the metal region formed over the first device region has a first thickness, and a second portion of the metal region formed over the second device region has a second thickness different from the first thickness.

14. The IC device of claim 13, further comprising a second plurality of interconnect layers over the first device region, wherein the first portion of the metal region is over the second plurality of interconnect layers.

15. The IC device of claim 13, further comprising a heat spreader over the metal region.

16. The IC device of claim 13, wherein the first device region forms a first processing unit, and the second device region forms a second processing unit.

17. The IC device of claim 13, wherein the first device region forms a first processing unit, and the second device region is a signal input/output region.

18. A method for forming an integrated circuit (IC) device comprising:
forming a device layer comprising a plurality of transistors;
forming a plurality of dummy layers over a first side of the device layer;
removing at least a portion of the plurality of dummy layers;
depositing a metal fill; and
forming a plurality of interconnect layers over a second side of the device layer, the second side opposite the first side.

19. The method of claim 18, further comprising depositing an etch stop over at least a portion of the device layer, wherein removing at least the portion of the plurality of dummy layers comprises removing dummy material to the etch stop.

20. The method of claim 18, wherein the metal fill comprises a first portion having a first thickness and a second portion having a second thickness different from the first thickness.
